(19) United States
(12) Patent Application Publication
(10) Pub. No.: US 2008/0212630 A1
(43) Pub. Date: Sep. 4, 2008

(54) Laser apparatus

(75) Inventors: Nobuyuki Otake, Nukata-gun (JP); Katsunori Abe, Chita-gun (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 12/071,928

(22) Filed: Feb. 28, 2008

(30) Foreign Application Priority Data
Mar. 1, 2007 (JP) 2007-51740

(51) Int. Cl. H01S 5/04; H01S 5/18

(52) U.S. Cl. 372/44.01

(57) ABSTRACT

A laser apparatus includes an excitation light generator for emitting excitation light and a wavelength converter including a solid laser medium for emitting laser light by converting a wavelength of the excitation light. The excitation light generator includes a surface-emitting laser having a first reflector with top and bottom reflectors and an active layer disposed between the top and bottom reflectors. The excitation light generator further includes a second reflector configured to highly reflect the excitation light. The solid laser medium is disposed between the surface-emitting laser device and the second reflector. Reflectivities of the top and bottom reflectors of the first reflector are set so that FWHM of the solid laser medium at the wavelength of the excitation light is greater than a resonance wavelength range of the surface-emitting laser device.

### CROSS REFERENCE TO RELATED APPLICATION

This application is based on and incorporates herein by reference Japanese Patent Application No. 2007-51740 filed on Mar. 1, 2007.

### FIELD OF THE INVENTION

The present invention relates to a laser apparatus for producing laser light by converting a wavelength of excitation light.

### BACKGROUND OF THE INVENTION

As disclosed in JP-A-2004-134633, U.S. Pat. No. 6,879,618 corresponding to JP-A-2005-20002, or US 20060083284 corresponding to JP-A-2006-113591, an apparatus has been proposed that produces laser light by converting a wavelength of excitation light. In an apparatus disclosed in JP-A-2004-134633, a phosphor layer is excited by excitation light emitted by a surface-emitting laser to produce light having a different wavelength from that of the excitation light. In an apparatus disclosed in U.S. Pat. No. 6,879,618, an organic active layer of a vertical laser cavity structure is excited by excitation light emitted by an organic light-emitting diode to produce laser light having a different wavelength from that of the excitation light. In an apparatus disclosed in US 20060083284, a surface-emitting laser device is excited by excitation light emitted by a semiconductor laser device, and a wavelength conversion element performs wavelength conversion of laser light from the surface-emitting laser device to produce visible laser light.

In the case of the apparatus disclosed in JP-A-2004-134633, the light outputted from the phosphor layer is incoherent light. Therefore, the apparatus disclosed in JP-A-2004-134633 cannot be used as a laser light source to produce coherent light. In the case of the apparatus disclosed in U.S. Pat. No. 6,879,618, the organic light-emitting diode as a excitation light source outputs incoherent light. Therefore, efficiency of conversion to laser light is low so that the apparatus cannot achieve high power laser output. In the case of the apparatus disclosed in US 20060083284, the surface-emitting laser device is excited by the semiconductor laser device. Since the apparatus disclosed in US 20060083284 requires two laser devices, it is difficult to reduce its size.

### SUMMARY OF THE INVENTION

In view of the above-described problem, it is an object of the present invention to provide a laser apparatus that has a reduced size and outputs laser light efficiently.

According to an aspect of the present invention, a laser apparatus includes an excitation light generator for emitting excitation light and a wavelength converter for emitting laser light by converting a wavelength of the excitation light. The excitation light generator includes a surface-emitting laser device that is formed on a semiconductor substrate and includes a first reflector having top and bottom reflectors and a semiconductor active layer disposed between the top and bottom reflectors. The excitation light is emitted through the top reflector of the surface-emitting laser device. The wavelength converter includes a solid laser medium layer that receives the excitation light and performs wavelength conversion of the excitation light.

The excitation light generator further includes a second reflector configured to highly reflect the excitation light. The solid laser medium layer is disposed between the surface-emitting laser device and the second reflector. A first reflectivity of the top reflector of the first reflector is greater than a second reflectivity of the bottom reflector of the first reflector. The first and second reflectivities are set to satisfy the following inequality,

$$FWHM > \frac{λ 0 ( 1 - R 1 \cdot R 2 )}{2 {π ( R 1 \cdot R 2 )}^{0.25}}$$

In the above inequality, R1, R2 represent the first and second reflectivities, respectively, λ0 represents the wavelength of the excitation light, and FWHM represents a full width at half maximum of an absorption spectrum of the solid laser medium layer at the wavelength of the excitation light. From the above inequality, the top and bottom reflectors of the first reflector are formed so that the FWHM of the solid laser medium layer at the wavelength of the excitation light is greater than a resonance wavelength range of the surface-emitting laser device. In such an approach, the surface-emitting laser device can be prevented from lasing at a wavelength outside the FWHM of the solid laser medium layer. Thus, the laser apparatus has improved energy conversion efficiency.

### BRIEF DESCRIPTION OF THE DRAWINGS

The above and other objectives, features and advantages of the present invention will become more apparent from the following detailed description made with check to the accompanying drawings. In the drawings:

FIG. 1 is a diagram illustrating a cross-sectional view of a laser apparatus according to a first embodiment of the present invention;

FIG. 2 is a diagram illustrating excitation and transition of an electron in a solid laser medium layer;

FIG. 3 is a diagram illustrating an absorption spectrum of the solid laser medium layer;

FIG. 4 is a diagram illustrating a relationship between a reflectivity of a reflector and a resonance wavelength range of a surface-emitting laser device;

FIG. 5 is a diagram illustrating a relationship between a reflectivity of a reflector and the number of pairs of layers of the reflector;

FIG. 6 is a diagram illustrating a cross-sectional view of a laser apparatus according to a second embodiment of the present invention;

FIG. 7 is a diagram illustrating a cross-sectional view of a laser apparatus according to a third embodiment of the present invention;

FIG. 8 is a diagram illustrating a cross-sectional view of a laser apparatus according to a fourth embodiment of the present invention;

FIG. 9 is a diagram illustrating a cross-sectional view of a laser apparatus according to a fifth embodiment of the present invention;

FIG. 10 is a diagram illustrating a cross-sectional view of a laser apparatus according to a sixth embodiment of the present invention;

FIG. 11 is a diagram illustrating a detailed view of FIG. 10;

FIG. 12 is a diagram illustrating a reflection characteristic of a third reflector of the laser apparatus of FIG. 10;

FIG. 13 is a diagram illustrating a relationship between a refractive index difference and a high reflection range of the third reflector;

FIG. 14 is a diagram illustrating a cross-sectional view of a laser apparatus according to a seventh embodiment of the present invention;

FIG. 15 is a diagram illustrating a cross-sectional view of a laser apparatus according to an eighth embodiment of the present invention;

FIG. 16 is a diagram illustrating a cross-sectional view of a laser apparatus according to a ninth embodiment of the present invention; and

FIG. 17 is a diagram illustrating a cross-sectional view of a laser apparatus according to a tenth embodiment of the present invention.

### DETAILED DESCRIPTION OF THE PREFERRED EMBODIMENTS

### First Embodiment

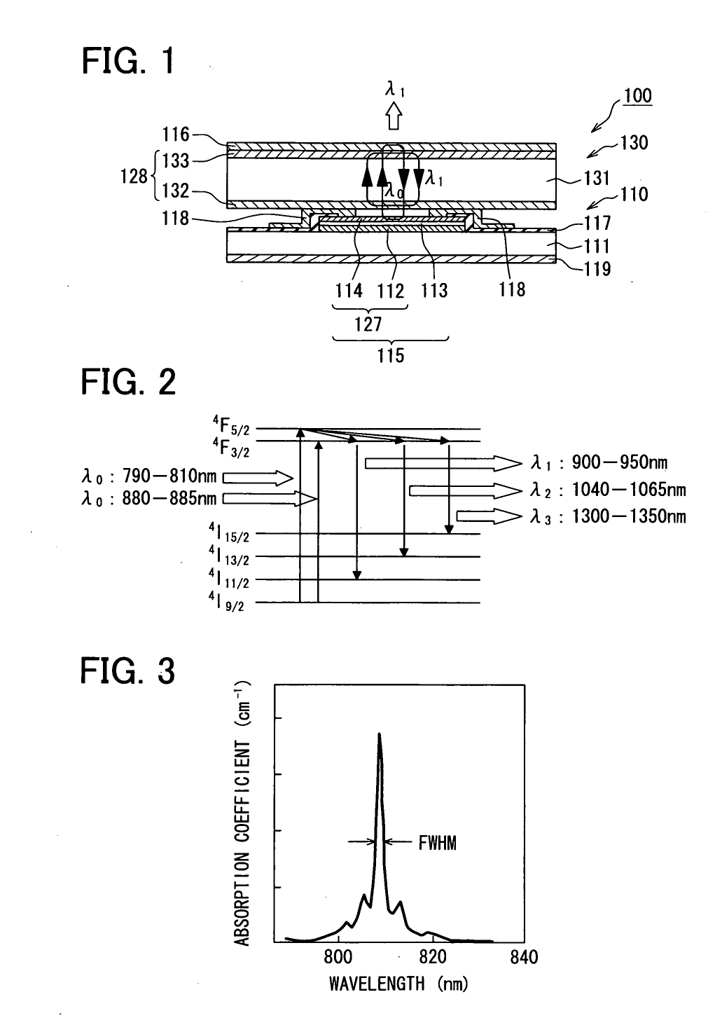

Referring to FIG. 1, a laser apparatus 100 according to a first embodiment of the present invention includes an excitation light generator 110 and a wavelength converter 130 having a solid laser media layer 131. The excitation light generator 110 outputs excitation (i.e., pump) light. The wavelength converter 130 receives the excitation light and outputs converted light with a wavelength different from that of the excitation light.

The excitation light generator 110 includes a surface-emitting laser device 115 formed on a semiconductor substrate 111. The surface-emitting laser device 115 includes a first reflector 127 and an active layer 113. The first reflector 127 includes a n-type bottom reflective layer 112 and a p-type top reflective layer 114 that are located on opposite sides of the active layer 113. The excitation light generator 110 further includes a second reflector 116. The surface-emitting laser device 115 and the second reflector 116 are located on opposite sides of the solid laser media layer 131. The second reflector 116 highly reflects the excitation light with a predetermined wavelength λ0.

The semiconductor substrate 111 is a n-type gallium arsenide (n-GaAs) substrate. The bottom reflective layer 112 is disposed on one side of the semiconductor substrate 111. The bottom reflective layer 112 includes multiple pairs of Al_{z1}Ga_{1-z1}As/Al_{z2}Ga_{1-z2}As layers doped with n-type dopants, where 0≦z1<z2≦1. Each pair of Al_{z1}Ga_{1-z1}As/Al_{z2}Ga_{1-z2}As layers includes a Al_{z1}Ga_{1-z1}As layer and a Al_{z2}Ga_{1-z2}As layer that are stacked together. Thus, the bottom reflective layer 112 is formed by alternately stacking multiple Al_{z1}Ga_{1-z1}As layers and multiple Al_{z2}Ga_{1-z2}As layers and configured as a distributed Bragg reflector (DBR).

A n-type n-AlGaAs cladding layer (not shown) is disposed on the bottom reflective layer 112. The active layer 113 is disposed on the n-AlGaAs cladding layer. A p-type p-AlGaAs cladding layer (not shown) is disposed on the active layer 113. The active layer 113 is a multiquantum well layer and includes multiple pairs of Alₓ₁In_{y1}Ga_{1-x1-y1}As/Alₓ₃In_{y3}Ga_{1-x3-y3}As layers. Each pair of Alₓ₁In_{y1}Ga_{1-x1-y1}As/Alₓ₃In_{y3}Ga_{1-x3-y3}As layers includes a Alₓ₁In_{y1}Ga_{1-x1-y1}As layer and a Alₓ₃In_{y3}Ga_{1-x3-y3}As layer that are stacked together. Thus, the active layer 113 is formed by alternately stacking multiple Alₓ₁In_{y1}Ga_{1-x1-y1}As layers and multiple Alₓ₃In_{y3}Ga_{1-x3-y3}As layers. The compositional ratio (i.e., x1, y1, x3, y3) and optical thickness of the active layer 113 are adjusted to output the excitation light with the wavelength λ0. The optical thickness of the active layer 113 is adjusted approximately equal to the wavelength λ0, and the wavelength λ0 is adjusted in a range from 790 nanometers (nm) to 810 nm. For example, the wavelength λ0 is adjusted to 808 nm. The wavelength λ0 is a peak wavelength of the excitation light.

The top reflective layer 114 is disposed on the p-AlGaAs cladding layer. The top reflective layer 114 includes multiple pairs of Al_{z3}Ga_{1-z3}As/Al_{z4}Ga_{1-z4}As layers doped with p-type dopants, where 0≦z3<z4≦1. Each pair of Al_{z3}Ga_{1-z3}As/Al_{z4}Ga_{1-z4}As layers includes a Al_{z3}Ga_{1-z3}As layer and a Al_{z4}Ga_{1-z4}As layer that are stacked together. Thus, the top reflective layer 114 is formed by alternately stacking multiple Al_{z3}Ga_{1-z3}As layers and multiple Al_{z4}Ga_{1-z4}As layers and configured as a distributed Bragg reflector (DBR).

The top reflective layer 114 has a first reflectivity R1 with respect to the excitation light. The optical thickness of each layer (i.e., each of the Al_{z3}Ga_{1-z3}As layer and the Al_{z4}Ga_{1-z4}As layer) of the top reflective layer 114 is set to a quarter of the wavelength λ0. The optical thickness is defined by the actual (i.e., physical) thickness of each layer times the refractive index of each layer. The bottom reflective layer 112 has a second reflectivity R2 with respect to the excitation light. The optical thickness of each layer (i.e., each of the Al_{z1}Ga_{1-z1}As and the Al_{z2}Ga_{1-z2}As) of the bottom reflective layer 112 is set to a quarter of the wavelength λ0. The refractive index of each layer is adjusted so that the second reflectivity R2 of the bottom reflective layer 112 can be greater than the first reflectivity R1 of the top reflective layer 114. In this way, the surface-emitting laser device 115 is constructed as a resonator, in which the active layer 113 are interposed between the bottom reflective layer 112 and the top reflective layer 114 of the first reflector 127. The excitation light emitted by the active layer 113 is multiply (repeatedly) reflected between the bottom and top reflective layers 112, 114 so that laser oscillation occurs. As a result, the excitation light is outputted from the surface-emitting laser device 115 through the top reflective layer 114.

A longitudinal mode control of the excitation light is performed in the surface-emitting laser device 115 to directly excite transitions between the energy levels of rare-earth ions or transition-metal ions doped to the solid laser medium layer 131. In such an approach, the energy conversion efficiency is improved so that the laser apparatus 100 can achieve high power laser output.

Each layer described above is formed by using a known crystal growth process such as a metalorganic chemical vapor deposition (MOCVD) method, a molecular light epitaxy (MBE) process, or the like. After each layer is formed, the surface-emitting laser device 115 is formed by using a mesa etching process, an insulating layer forming process, an electrode layer deposition process, and the like. By the way, in FIG. 1, a numeral 117 designates an insulating film (e.g., silicon oxide film) to confine light and current in a horizontal direction (i.e., a direction of the plane of the semiconductor substrate 111). A numeral 118 designates a p-type electrode (e.g., Cr/Pt/Au), and a numeral 119 designates an n-type electrode (e.g., Au—Ge/Ni/Au).

To improve energy conversion efficiency (i.e., efficiency of electricity to light conversion), it is preferable that Al compositional ratios z1-z4 of the bottom and top reflective layers 112, 114 should be adjusted so that the excitation light with the wavelength λ0 cannot be absorbed. Such Al compositional ratios have been empirically known. For example, when the wavelength λ0 is 880 nm, the energy conversion efficiency can be improved by setting the Al compositional ratios z1-z4 equal to or greater than 0.12. For another example, when the wavelength λ0 is 808 nm, the energy conversion efficiency can be improved by setting the Al compositional ratios z1-z4 equal to or greater than 0.23. Although GaAs has a small bandgap, the bandgap of the bottom and top reflective layers 112, 114 can be increased by setting the Al compositional ratios z1-z4 according to the wavelength λ0 of the excitation light. Thus, the absorption of the excitation light by the bottom and top reflective layers 112, 114 can be prevented. In the first embodiment, the wavelength λ0 of the excitation light is set to 808 nm, and the Al compositional ratios z1-z4 are set equal to or greater than 0.23.

Low heat dissipation from the active layer 113 to the outside of the surface-emitting laser device 115 may cause problems such as a reduction in reliability (life) of the surface-emitting laser device 115, a variation in the magnitude of the excitation light, and a variation in the wavelength λ0 of the excitation light. Therefore, it is preferable that the Al compositional ratios z1-z4 of the bottom and top reflective layers 112, 114 be adjusted by taking into consideration heat conductivity of the bottom and top reflective layers 112, 114 in addition to the energy conversion efficiency.

The heat conductivity of the bottom reflective layer 112 increases as the Al compositional ratio z1 is closer to 0 (zero), and the Al compositional ratio z2 is closer to 1 (one). However, the energy conversion efficiency of the bottom reflective layer 112 decreases as the Al compositional ratio z1 is closer to 0. In practice, therefore, it is preferable that the Al compositional ratio z2 be set to 1, and the Al compositional ratio z1 be set as close to zero as possible in a range where the absorption of the excitation light can be suitably prevented. In this case, the bottom reflective layer 112 is a Al_{z1}Ga_{1-z1}As/AlAs layer, where 0<z1<1. As described above, when the Al compositional ratios z1-z4 are set equal to or greater than 0.23, the absorption of the excitation light can be suitably prevented. Therefore, for example, the Al compositional ratio z1 is set to 0.23.

Likewise, the heat conductivity of the top reflective layer 114 increases as the Al compositional ratio z3 is closer to 0 (zero), and the Al compositional ratio z4 is closer to 1 (one). However, the energy conversion efficiency of the top reflective layer 114 decreases as the Al compositional ratio z3 is closer to 0. In practice, therefore, it is preferable that the Al compositional ratio z4 be set to 1, and the Al compositional ratio z3 be set as close to zero as possible in a range where the absorption of the excitation light can be suitably prevented. In this case, the top reflective layer 114 is a Al_{z3}Ga_{1-z3}As/AlAs layer, where 0<z3<1. As described above, when the Al compositional ratios z1-z4 are set equal to or greater than 0.23, the absorption of the excitation light can be suitably prevented. Therefore, for example, the Al compositional ratio z3 is set to 0.23.

In such an approach, while the heat conductivity of the bottom and top reflective layers 112, 114 is improved, the absorption of the excitation light by the bottom and top reflective layers 112, 114 can be efficiently prevented. Accordingly, the heat dissipation from the active layer 113 to the outside of the surface-emitting laser device 115 increases.

The bottom and top reflective layers 112, 114 have opposite conductivity types. Specifically, the conductive type of the bottom reflective layer 112 is a p-type, and the conductive type of the top reflective layer 114 is a n-type. However, the bottom and top reflective layers 112, 114 are the same in composition, i.e., z1=z3, and z2=z4. In the present embodiment, as described above, the Al compositional ratios z1, z3 are set to 0.23, and the Al compositional ratios z2, z4 are set to 1. In this case, each of the bottom and top reflective layers 112, 114 is a Al_{0.23}Ga_{0.77}As/AlAs layer. Since the bottom and top reflective layers 112, 114 are the same in composition, the bottom and top reflective layers 112, 114 can be simplified in structure. Each of the bottom and top reflective layers 112, 114 is formed from multiple pairs of the Al_{0.23}Ga_{0.77}As/AlAs layers. The reflectivity R1 of the bottom reflective layers 112 can be adjusted by adjusting the number of the pairs of the Al_{0.23}Ga_{0.77}As/AlAs layers. Likewise, the reflectivity R2 of the top reflective layers 114 can be adjusted by adjusting the number of the pairs of the Al_{0.23}Ga_{0.77}As/AlAs layers. Thus, each of the reflectivity R1, R2 depend on one parameter (i.e., the number of the pairs of the Al_{0.23}Ga_{0.77}As/AlAs layers). Therefore, the surface-emitting laser device 115 can be simplified in structure.

The second reflector 116 is disposed on a light-emitting surface of the wavelength converter 130. The second reflector 116 includes multiple pairs of two different types of dielectric layers having different refractive indexes. In the present embodiment, the second reflector 116 includes multiple pairs of Al₂O₃/TiO₂ layers. Each pair of Al₂O₃/TiO₂ layers includes a Al₂O₃ layer and a TiO₂ layer that are stacked together. Thus, the second reflector 116 is formed by alternately stacking multiple Al₂O₃ layers and multiple TiO₂ layers and configured as a distributed Bragg reflector (DBR). The second reflector 116 is formed on a light-emitting surface of the solid laser medium layer 131 through a top reflective layer 133 of a third reflector 128 by using a deposition method, a sputtering method, and the like. The third reflector 128 is described later. The thickness of each layer (i.e., each of the Al₂O₃ layer and the TiO₂ layer) of the second reflector 116 is set so that the second reflector 116 can highly reflect the excitation light with the wavelength λ0.

Using the second reflector 116 brings the following advantages. As shown in FIG. 1, the excitation light with the wavelength λ0 is multiply (i.e., repeatedly) reflected through the solid laser medium layer 131 between the second reflector 116 and the top reflective layer 114 of the first reflector 127. Thus, the excitation light is efficiently absorbed by the solid laser medium layer 131 so that the energy conversion efficiency can be improved. In the case of FIG. 1, the second reflector 116 is disposed on the solid laser medium layer 131 through the top reflector 133. Alternatively, the second reflector 116 can be directly disposed on the solid laser medium layer 131, and the top reflector 133 can be disposed on the solid laser medium layer 131 through the second reflector 116.

Next, the wavelength converter 130 is described below. The wavelength converter 130 includes the solid laser medium layer 131 and the third reflector 128. The solid laser medium layer 131 receives (i.e., absorbs) the excitation light and outputs converted light with a different wavelength from that of the excitation light. The third reflector 128 includes a bottom reflective layer 132 and the top reflective layer 133 that are placed on opposite sides of the solid laser medium layer 131 in a direction the excitation light travels. Each of the bottom and top reflective layers 132, 133 highly reflect the converted light with a predetermined wavelength. Thus, the converted light with the predetermined wavelength resonates between the bottom and top reflective layers 132, 133 so that high power laser oscillation can occur.

The bottom reflective layer 132 of the third reflector 128 is disposed on an light receiving surface of the solid laser medium layer 131, and the top reflective layer 133 of the third reflector 128 is disposed on the light-emitting surface of the solid laser medium layer 131. The excitation light is inputted from the surface-emitting laser device 115 to the solid laser medium layer 131 through the bottom reflective layer 132, and the converted light is outputted from the solid laser medium layer 131 through the top reflective layer 133. Thus, the wavelength converter 130 is disposed on a light-emitting surface of the excitation light generator 110 through the bottom reflective layer 132 of the third reflector 128. The solid laser medium layer 131 is formed from a neodymium doped yttrium aluminium garnet (Nd:YAG i.e., Nd:Y₃Al₅O₁₂) crystal. Neodymium (Nd) is a rare earth ion. The solid laser medium layer 131 is disposed to cover the entire light-emitting surface of the surface-emitting laser device 115 of the excitation light generator 110.

When the solid laser medium layer 131 receives the excitation light with the wavelength λ0 in a range from 790 nm to 810 nm, electrons in the solid laser medium layer 131 are selectively excited between the dopant neodymium (Nd) ion energy levels, which range from ⁴I_{9/2} to ⁴F_{5/2}. As shown in FIG. 2, each electron excited to the energy level ⁴F_{5/2} go down to the energy level ⁴F_{3/2} in a non-radiative transition. Then, each electron moves from the energy level ⁴F_{3/2} to one of the energy levels ⁴I_{11/2}, ⁴I_{13/2}, and ⁴I_{15/2}. The transition of the electron from the energy level ⁴F_{3/2} to the energy level ⁴I_{11/2} produces light with a peak wavelength λ1 ranging from 900 nm to 950 nm (e.g., 946 nm). The transition of the electron from the energy level ⁴F_{3/2} to the energy level ⁴I_{13/2} produces light with a peak wavelength λ2 ranging from 1040 nm to 1065 nm (e.g., 1064 nm). The transition of the electron from the energy level ⁴F_{3/2} to the energy level ⁴I_{15/2} produces light with a peak wavelength λ3 ranging from 1300 nm to 1350 nm (e.g., 1319 nm).

The wavelength λ0 of the excitation light can be changed by adjusting the thickness or the compositional ratios X1, X3, Y1, Y3 of the active layer 113 of the surface-emitting laser device 115. For example, when the wavelength λ0 of the excitation light is set to from 880 nm to 885 nm, electrons are selectively excited between the dopant neodymium (Nd) ion energy levels ranging from ⁴I_{9/2} to ⁴F_{3/2}. As shown in FIG. 2, each electron moves from the energy level ⁴F_{3/2} to one of the energy levels ⁴I_{11/2}, ⁴I_{13/2}, and ⁴I_{15/2}. The transition of the electron from the energy level ⁴F_{3/2} to the energy levels ⁴I_{11/2}, ⁴I_{13/2} and ⁴I_{15/2} produce light with the respective peak wavelengths λ1, λ2, and λ3. Since the non-radiative transition from the energy level ⁴F_{5/2} to the energy level ⁴F_{3/2} does not occur, the energy conversion efficiency can be improved accordingly.

The converted light outputted from the solid laser medium layer 131 selectively resonates between the bottom and top mirrors layer 132, 133 of the third reflector 128 at a predetermined wavelength, so that the laser apparatus 100 can emit light with the predetermined wavelength. In the present embodiment, as shown in FIG. 1, the converted light resonates between the bottom and top reflective layers 132, 133 at the wavelength λ1. Each of the bottom and top reflective layers 132, 133 includes multiple pairs of Al₂O₃/TiO₂ layers. Each pair of the Al₂O₃/TiO₂ layers includes a Al₂O₃ layer and a TiO₂ layer that are stacked together. Thus, each of the bottom and top reflective layers 132, 133 is formed by alternately stacking multiple Al₂O₃ layers and multiple TiO₂ layers and configured as a distributed Bragg reflector (DBR). For example, each of the bottom and top reflective layers 132, 133 can be formed by using a deposition method, a sputtering method, and the like.

The optical thickness of each layer (i.e., each of the Al₂O₃ layer and the TiO₂ layer) of the third reflector 128 is set to a quarter of the resonant wavelength λ1. The optical thickness is defined by the actual (i.e., physical) thickness of each layer times the refractive index of each layer. Thus, the converted light outputted from the solid laser medium layer 131 selectively resonates at the wavelength λ1 so that laser oscillation occurs. The bottom reflective layer 132 has a reflectivity with respect to the resonant wavelength λ1 greater than that of the top reflective layer 133. Thus, when the laser oscillation occurs, the converted light with the wavelength λ1 is outputted through the top reflective layer 133.

The resonant wavelength can be selectively changed between λ1-λ3 by adjusting at least one of the material (i.e., refractive index), the thickness, and the number of the pairs of the Al₂O₃/TiO₂ layers of the bottom and top mirrors layer 132, 133 of the third reflector 128. Thus, the laser apparatus 100 can selectively emit laser light with one of the wavelengths λ1-λ3

FIG. 3 shows absorption spectrum of the solid laser medium layer 131 with respect to the excitation light emitted by the surface-emitting laser device 115. In the case of FIG. 3, the solid laser medium layer 131 is formed from a Nd:YAG crystal, and the wavelength λ0 of the excitation light is 808 nm. As can be seen from FIG. 3, the full width at half maximum (FWHM), i.e., an absorption wavelength range of the solid laser medium layer 131 is very small and ranges from about 1 nm to about 3 nm. This small FWHM results in a poor energy conversion efficiency of a typical solid laser. It has been known that a resonance wavelength range F of the surface-emitting laser device 115 is given as follows by using the reflectivity R1, R2 of the top reflective layers 114, 112:

$$F = \frac{λ 0 ( 1 - R 1 \cdot R 2 )}{2 {π ( R 1 \cdot R 2 )}^{0.25}} \qquad ( 1 )$$

For example, if the FWHM of the solid laser medium layer 131 is smaller than the resonance wavelength range F of the surface-emitting laser device 115, the excitation light with a wavelength, which is inside the resonance wavelength range F and outside the FWHM, cannot be absorbed by the solid laser medium layer 131 while being repeatedly reflected between the second reflector 116 and the top reflective layer 114 of the first reflector 127. As a result, the surface-emitting laser device 115 is likely to lase at a wavelength outside the FWHM of the solid laser medium layer 131, and the energy conversion efficiency decreases.

In the present embodiment, to prevent the decrease in the energy conversion efficiency, the reflectivity R1, R2 of the top reflective layers 114, 112 of the first reflector 127 are adjusted to satisfy the following inequality:

$$FWHM > \frac{λ 0 ( 1 - R 1 \cdot R 2 )}{2 {π ( R 1 \cdot R 2 )}^{0.25}} \qquad ( 2 )$$

As can be understood from the above inequality (2), the top and bottom reflective layers 114, 112 are formed so that the FWHM of the solid laser medium layer 131 at the wavelength λ0 of the excitation light is greater than the resonance wavelength range F of the surface-emitting laser device 115. In such an approach, the surface-emitting laser device 115 can be prevented from lasing at the wavelength outside the FWHM of the solid laser medium layer 131. Therefore, the laser apparatus 100 has improved energy conversion efficiency.

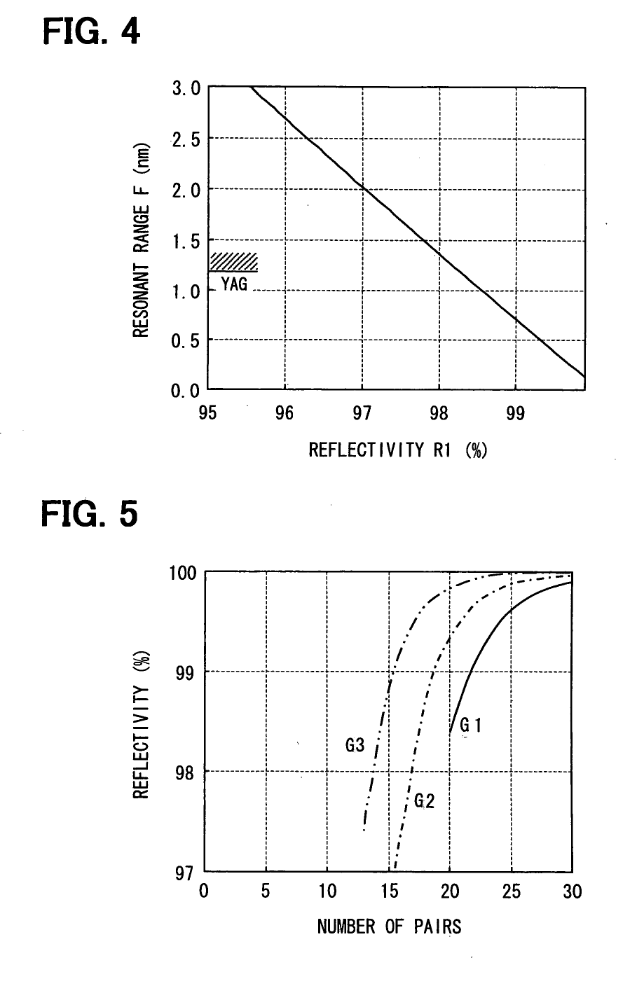

As an example, FIG. 4 shows a relationship between the reflectivity R1 of the top reflective layer 114 of the first reflector 127 and the resonance wavelength range F of the surface-emitting laser device 115 (i.e., the solid laser medium layer 131) under a condition where the wavelength λ0 of the excitation light is 808 nm, and the reflectivity R2 of the bottom reflective layer 112 of the first reflector 127 is fixed to 99.9 percents (%). When the solid laser medium layer 131 is formed from a Nd:YAG crystal, the FWHM of the solid laser medium layer 131 at the wavelength λ0 is 1.2 nm. Therefore, as can be seen from FIG. 4, the inequality (2) can be satisfied when the reflectivity R1 of the top reflective layer 114 is greater than about 98.3%.

The FWHM of the solid laser medium layer 131 depends on its base material. For example, when the solid laser medium layer 131 is formed from a neodymium doped yttrium vanadate (Nd:YVO, i.e., Nd:YVO₄) crystal, the FWHM of the solid laser medium layer 131 at the peak wavelength λ0 of 808 nm is between about 1.3 nm and 1.7 nm. For another example, when the solid laser medium layer 131 is formed from a neodymium-doped gadolinium orthovanadate (Nd:GVO, i.e., Nd:GdVO₄) crystal, the FWHM of the solid laser medium layer 131 at the wavelength λ0 of 808 nm is between about 1.4 nm and 1.5 nm.

Further, the FWHM of the solid laser medium layer 131 depends on the peak wavelength λ0 of the excitation light. For example, when the solid laser medium layer 131 is formed from a Nd:YAG crystal, and the peak wavelength λ0 of the excitation light is 885 nm, the FWHM of the solid laser medium layer 131 is about 2.8 nm. Thus, the FWHM of the solid laser medium layer 131 can be increased to 2.8 nm by using the excitation light with the peak wavelength λ0 of 885 nm. Therefore, at least one of the reflectivity R1, R2 of the first reflector 127 can be reduced.

As described previously, each of the bottom and top reflective layers 112, 114 is formed with multiple pairs of Al_{0.23}Ga_{0.77}As/AlAs layers. A graph G1 of FIG. 5 represents a relationship between a reflectivity and the number of pairs of Al_{0.23}Ga_{0.77}As/AlAs layers. As can be seen from FIG. 4, when the peak wavelength λ0 of the excitation light is 808 nm, the inequality (2) can be satisfied by setting the reflectivity R1 of the top reflective layer 114 greater than about 98.3%. As can be seen from FIG. 5, when the number of the pairs of the Al_{0.23}Ga_{0.77}As/AlAs layers is equal to or greater than twenty-two (i.e., 20), the reflectivity R1 can exceed 98.3%. In the case of FIG. 4, the reflectivity R2 of the top reflective layer 114 is fixed to 99.9%. From FIG. 5, when the number of the pairs of the Al_{0.23}Ga_{0.77}As/AlAs layers is equal to or greater than thirty (i.e., 30), the reflectivity R2 can be equal to or greater than 99.9%. Thus, the number of the pairs of the Al_{0.23}Ga_{0.77}As/AlAs layers of the bottom and top reflective layers 112, 114 is determined to satisfy the inequality (2) by taking into consideration the graph G1 of FIG. 5. A graph G2 of FIG. 5, serving as a reference example, represents a case where the peak wavelength λ0 of the excitation light is 880 nm, and each of the bottom and top reflective layers 112, 114 is formed with multiple pairs of Al_{0.12}Ga_{0.88}As/AlAs layers. A graph G3 of FIG. 5, serving as another reference example, represents a case where each of the bottom and top reflective layers 112, 114 is formed with multiple pairs of GaAs/AlAs layers, which are generally used in a distributed Bragg reflector (DBR).

As described above, according to the laser apparatus 100 of the first embodiment, the surface-emitting laser device 115 generates the excitation light with the wavelength λ0. The wavelength converter 130 convents the excitation light with the wavelength λ0 to the converted light with the wavelength λ1 different from the wavelength λ1. In such an approach, the laser apparatus 100 can be reduced in size. Further, components of the laser apparatus 100 are integrally stacked together so that the size of the laser apparatus 100 can be efficiently reduced.

The longitudinal mode control of the excitation light is performed in the surface-emitting laser device 115 to directly excite transitions between the energy levels of rare-earth ions or transition-metal ions doped to the solid laser medium layer 131. In such an approach, the energy conversion efficiency is improved so that the laser apparatus 100 can achieve high power laser output.

The excitation light with the wavelength λ0 is multiply, repeatedly reflected through the solid laser medium layer 131 between the second reflector 116 and the top reflective layer 114 of the first reflector 127. Thus, the solid laser medium layer 131 can efficiently absorb the excitation so that the energy conversion efficiency can be improved.

As can be seen from the inequality (2), the top and bottom reflective layers 114, 112 are formed so that the FWHM of the solid laser medium layer 131 at the wavelength λ0 of the excitation light is greater than the resonance wavelength range F of the surface-emitting laser device 115. In such an approach, the surface-emitting laser device 115 can be prevented from lasing at a wavelength outside the FWHM of the solid laser medium layer 131. Therefore, the laser apparatus 100 has improved energy conversion efficiency.

The solid laser medium layer 131 is formed from a Nd:YAG crystal, which produces light with the wavelengths λ1-λ3 by receiving the excitation light with the wavelength λ0. Alternatively, the solid laser medium layer 131 can be formed from a base material other than a Nd:YAG crystal. For example, the solid laser medium layer 131 can be formed from a ytterbium doped yttrium aluminium garnet (Yb:YAG i.e., Yb:Y₃Al₅O₁₂) crystal. In this case, when the solid laser medium layer 131 receives the excitation light with the wavelength λ0 in a range from 900 nm to 985 nm, electrons in the solid laser medium layer 131 are selectively excited between the dopant ytterbium (Yb) ion energy levels, which range from ²F_{5/2} to ²F_{7/2}. Each electron excited to the energy level ²F_{7/2} moves to the energy level ²F_{5/2}. The transition of the electron from the energy level ²F_{7/2} to the energy level ²F_{5/2} produces light with a peak wavelength ranging from 1000 nm to 1085 nm. For another example, the solid laser medium layer 131 can be formed from a rare-earth ion or transition metal ion doped crystal such as a YVO (Y₃Al₅O₁₂) crystal, a GVO (GdVO₄) crystal, a GGO (Gd₃Ga₅O₁₂) crystal, a SVAP (Sr₅(VO₄)₃F) crystal, a FAP ((PO₄)₃F) crystal, a SFAP (Sr₅(PO₄)₃F) crystal, a YLF (YLiF₄) crystal, or the like.

The active layer 113 of the surface-emitting laser device 115 is formed from multiple pairs of Alₓ₁In_{y1}Ga_{1-x1-y1}As/Alₓ₃In_{y3}Ga_{1-x3-y3}As multiquantum well layers. Alternatively, the active layer 113 can be formed from multiquantum well layers other than the Alₓ₁In_{y1}Ga_{1-x1-y1}As/Alₓ₃In_{y3}Ga_{1-x3-y3}As according to the peak wavelength λ0 of the excitation light. For example, the active layer 113 can be formed from multiple pairs of Inₓ₂Ga₁₋ₓ₂Asₓ₂P_{1-y2}/Inₓ₄Ga₁₋ₓ₄As_{y4}P_{1-y4} multiquantum well layers.

The wavelength converter 130 is disposed on the light-emitting surface of the excitation light generator 110 through the bottom reflective layer 132 of the third reflector 128. In short, the wavelength converter 130 is in direct contract with the excitation light generator 110. In such an approach, the laser apparatus 100 can be reduced in size. Further, since a distance from the active layer 113 to the solid laser medium layer 131 is small, a loss in the excitation light can be reduced so that the laser apparatus 100 can achieve high power laser output. Alternatively, the wavelength converter 130 can be disposed above the light-emitting surface of the excitation light generator 110 with a space therebetween.

The semiconductor substrate 111 is a n-type gallium arsenide (n-GaAs) substrate. Alternatively, the semiconductor substrate 111 can be a semiconductor substrate other than the n-GaAs substrate. For example, the semiconductor substrate 111 can be a p-type gallium arsenide (p-GaAs) substrate. In this case, the conductive type of the bottom reflective layer 112 is changed from a p-type to n-type, and the conductive type of the top reflective layer 114 is changed from a n-type to a p-type.

The wavelength λ0 of the excitation light emitted by the surface-emitting laser device 115 is 808 nm. Alternatively, the wavelength λ0 of the excitation light emitted by the surface-emitting laser device 115 can be other than 808 nm. For example, the surface-emitting laser device 115 can emit the excitation light with the wavelength λ0 of 880 nm the wavelength λ0 by adjusting the thickness or the compositional ratios X1, X3, Y1, Y3 of the active layer 113. As can be understood from the graph G2 of FIG. 5, when the wavelength λ0 is 880 nm, the reflectivity R1 of the top reflective layer 114 can be equal to or greater than 98.3% by forming the top reflective layer 114 using 18 or more pairs of Al_{0.12}Ga_{0.88}As/AlAs layers. Likewise, the reflectivity R2 of the bottom reflective layer 112 can be equal to or greater than 99.9% by forming the bottom reflective layer 112 using 30 or more pairs of Al_{0.12}Ga_{0.88}As/AlAs layers. Thus, the inequality (2) can be satisfied.

### Second Embodiment

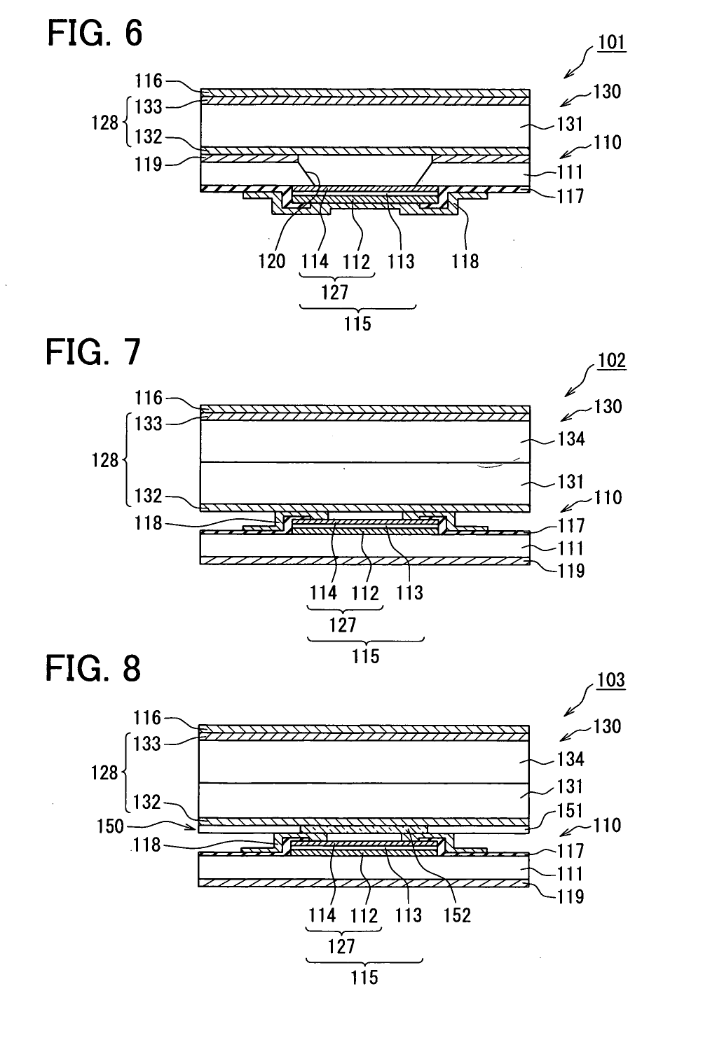

A laser apparatus 101 according to a second embodiment of the present invention is described below with reference to FIG. 6. Differences between the laser apparatus 100, 101 are as follows.

As shown in FIG. 1, according to the laser apparatus 100 of the first embodiment, the semiconductor substrate 111 is located on a side of the bottom reflective layer 112 of the first reflector 127. Therefore, the surface-emitting laser device 115 emits the excitation light in a direction opposite to the semiconductor substrate 111. In contrast, as shown in FIG. 6, according to the laser apparatus 101 of the second embodiment, the semiconductor substrate 111 is located on a side of the top reflective layer 114 of the first reflector 127. Therefore, the surface-emitting laser device 115 emits the excitation light in a direction to the semiconductor substrate 111.

The excitation light emitted by the active layer 113 resonates between the bottom and top reflective layers 112, 114. Thus, laser oscillation occurs so that the surface-emitting laser device 115 emits the excitation light through the top reflective layer 114. The semiconductor substrate 111 has a slit portion 120 at a location corresponding to the surface-emitting laser device 115. The slit portion 120 is open to the light-emitting surface of the surface-emitting laser device 115. The bottom of the slit portion 120 is larger in size (diameter) than the light-emitting surface of the surface-emitting laser device 115 so that the excitation light emitted by the surface-emitting laser device 115 can reach the solid laser medium layer 131 without being absorbed or obstructed by the semiconductor substrate 111. For example, the slit portion 120 can be formed by etching the semiconductor substrate 111. In the second embodiment, the electrode 119 is formed on one side of the semiconductor substrate 111 without the slit portion 120 in such a manner that the wavelength converter 130 is disposed on the excitation light generator 110 through the electrode 119.

As described above, according to the laser apparatus 101 of the second embodiment, the semiconductor substrate 111 is located on the side of the top reflective layer 114, not the bottom reflective layer 112. In such an approach, the heat dissipation from the active layer 113 to the outside of the surface-emitting laser device 115 can be improved. Therefore, the laser apparatus 101 can achieve high-power laser output. The bottom reflective layer 112 can be provided with a heat radiator such as a heat sink to enhance the heat dissipation. The slit portion 120 of the semiconductor substrate 111 can be at least partially filled with a material that cannot easily absorb the excitation light emitted by the surface-emitting laser device 115.

### Third Embodiment

A laser apparatus 102 according to a third embodiment of the present invention is described below with reference to FIG. 7. Differences between the laser apparatus 100, 102 are as follows.

As can be seen by comparing FIG. 1 with FIG. 7, the laser apparatus 102 further includes a wavelength conversion element 134 that is disposed on the light-emitting surface of the solid laser medium layer 131. The bottom reflective layer 132 of the third reflector 128, the solid laser medium layer 131, the wavelength conversion element 134, the top reflective layer 133 of the third reflector 128, and the second reflector 116 are integrally stacked together in that order so that the laser apparatus 102 can be reduced in size.

The solid laser medium layer 131 selectively converts the excitation light with the wavelength λ0 to the light with the wavelengths λ1-λ3. The wavelength conversion element 134 converts the light with the wavelengths λ1-λ3 to light with wavelengths different from the wavelengths λ1-λ3, respectively. The wavelength conversion element 134 is formed from a nonlinear crystal to generate the second harmonic of the light with the wavelengths λ1-λ3. The nonlinear crystal can be selected according to the wavelengths λ1-λ3. For example, the wavelength conversion element 134 can be formed from a nonlinear crystal such as a KTP (KTiOPO₄) crystal, a LBO (LiB₃O₅) crystal, a BiBO (BiB₃O₆) crystal, or a PPKTP (periodically poled KTP) crystal.

According to the laser apparatus 102 of the third embodiment, the wavelength conversion element 134 can respectively convert light with wavelengths λ1-λ3 in the near-infrared range to light with wavelengths λ4-λ6 in the visible range. For example, the wavelength λ1 of between about 900 nm and 950 nm is converted to the wavelength λ4 of between about 450 nm and 475 nm, the wavelength λ2 of between about 1040 nm and 1065 nm is converted to the wavelength λ5 of between about 520 nm and 533 nm, and the wavelength λ3 of between about 1300 nm and 1350 nm is converted to the wavelength λ6 of between about 650 nm and 675 nm. Thus, the laser apparatus 102 can be used as a RGB light source.

As shown in FIG. 7, the wavelength conversion element 134 is disposed on the light-emitting surface of the solid laser medium layer 131. Alternatively, the wavelength conversion element 134 can be disposed on the top reflective layer 133 of the third reflector or the second reflector 116. The wavelength conversion element 134 is formed from a nonlinear crystal to generate the second harmonic. Alternatively, the wavelength conversion element 134 can be formed from a base material other than the nonlinear crystal to generate the second harmonic, as long as the base material can achieve the wavelength conversion. The second and third embodiments can be combined together.

### Fourth Embodiment

A laser apparatus 103 according to a fourth embodiment of the present invention is described below with reference to FIG. 8. Differences between the laser apparatus 102, 103 are as follows.

As can be seen by comparing FIG. 6 with FIG. 7, the laser apparatus 103 further includes a lens member 150 having a microlens 152. The lens member 150 is disposed between the excitation light generator 110 and the wavelength converter 130 to gather or collimate the excitation light from the excitation light generator 110. The collimated or gathered light can efficiently excite the solid laser medium layer 131. Thus, the energy conversion efficiency is improved so that the laser apparatus 103 can achieve high-power laser output.

For example, the lens member 150 includes a base 151 formed from glass. The base 151 is processed by a photolithography method and an ionic diffusion method so that a flat gradient index microlens 152 can be formed. The microlens 152 is positioned with respect to the surface-emitting laser device 115 so that the optical axis of the microlens 152 can coincide with the axis of the excitation light from the surface-emitting laser device 115. The microlens 152 is equal to or larger in size (diameter) than the light-emitting surface of the surface-emitting laser device 115 to efficiently collimate or gather the excitation light emitted by the surface-emitting laser device 115.

The lens member 150 is disposed on the light-emitting surface of the excitation light generator 110, and the wavelength converter 130 is disposed on the lens member 150 through the bottom reflective layer 132 of the third reflector 128. The excitation light generator 110 and the lens member 150 are bonded together in a known bonding method (e.g., by adhesive). The lens member 150 and the wavelength converter 130 are bonded together in a known bonding method (e.g., by adhesive). Thus, the excitation light generator 110, the lens member 150, and the wavelength converter 130 are integrated together.

According to the laser apparatus 103 of the fourth embodiment, the laser apparatus 103 includes a lens member 150 to gather or collimate the excitation light from the excitation light generator 110. The collimated or gathered light can efficiently excite the solid laser medium layer 131. Thus, the energy conversion efficiency is improved so that the laser apparatus 103 can achieve high-power laser output. Since the lens member 150 is a flat-type lens, the excitation light generator 110, the lens member 150, and the wavelength converter 130 are integrally stacked together so that the laser apparatus 100 can be reduced in size. Further, since a distance from the surface-emitting laser device 115 (i.e., the active layer 113) to the wavelength converter 130 (i.e., the solid laser medium layer 131) is small, a loss in the excitation light can be reduced so that the laser apparatus 103 can achieve high power laser output.

The lens member 150 can be disposed on the light-emitting surface of the wavelength converter 130 instead of between the excitation light generator 110 and the wavelength converter 130. In such an approach, the shape of a laser light outputted from the laser apparatus 103 can be controlled by the lens member 150. In this case, the microlens 152 can be a convex lens, which is formed by a reflow method, an inkjet method, a grayscale mask method, or the like. Alternatively, the lens member 150 can be disposed not only between the excitation light generator 110 and the wavelength converter 130 but also on the light-emitting surface of the wavelength converter 130. The fourth embodiment can be combined together with the first embodiment or the second embodiment. For example, the lens member 150 can be disposed on the bottom of the slit portion 120 of the second embodiment.

### Fifth Embodiment

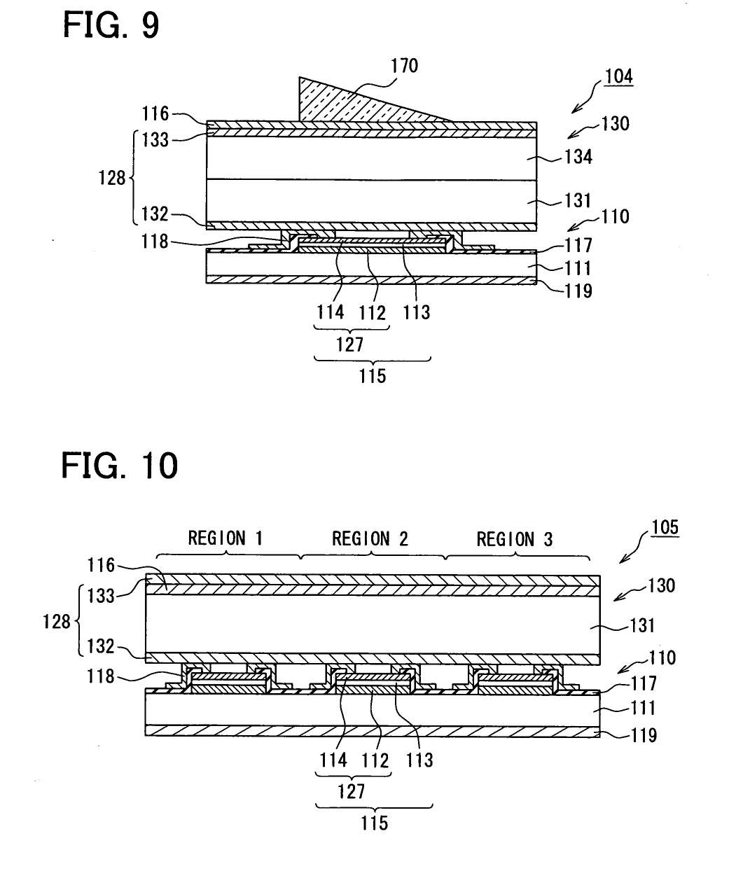

A laser apparatus 104 according to a fifth embodiment of the present invention is described below with reference to FIG. 9. Differences between the laser apparatus 102, 104 are as follows.

As can be seen by comparing FIG. 7 with FIG. 9, the laser apparatus 104 further includes an optical element 170 for controlling a direction of the laser light outputted from the laser apparatus 104. The optical element 170 may be, for example, a microprism. The optical element 170 is disposed on the second reflector 116 above the light-emitting surface of the wavelength converter 130. The optical element 170 is integrally stacked on the second reflector 116 so that the laser apparatus 104 can be reduced in size. Alternatively, the optical element 170 can be disposed separately from the second reflector 116, as long as the optical element 170 is located above the light-emitting surface of the wavelength converter 130.

The optical element 170 can be other than a microprism. For example, the optical element 170 can be an electrostatically-driven mirror, which is formed on a semiconductor substrate by microelectromechanical system (MEMS). The angle of the electrostatically-driven mirror can be adjusted so that the optical element 170 can control the direction of the laser light at any desired direction. The fifth embodiment can be combined together with the first embodiment, the second embodiment, or the fourth embodiment.

### Sixth Embodiment

A laser apparatus 105 according to a sixth embodiment of the present invention is described below with reference to FIGS. 10-13. Differences between the laser apparatus 100, 105 are as follows.

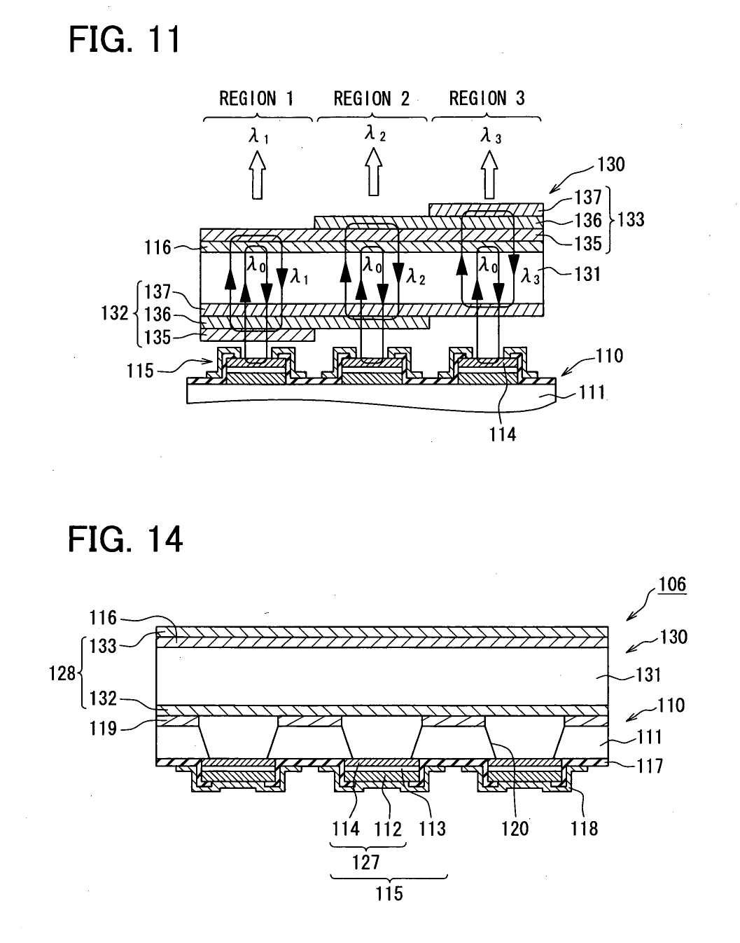

The laser apparatus 100 of the first embodiment is modified as the laser apparatus 105 to output multiple laser light with different wavelengths. The laser apparatus 105 includes a plurality of surface-emitting laser devices 115 that are arranged on a single semiconductor substrate 111 in a two-dimensional array. The wavelength converter 130 is divided into a plurality of regions, each of which is provided with a corresponding one of the surface-emitting laser devices 115. Each region of the wavelength converter 130 outputs laser light with a different wavelength so that the laser apparatus 105 can output multiple laser light with different wavelengths. For example, as shown in FIGS. 10, 11, the wavelength converter 130 is divided into three regions 1-3 that output laser light with wavelengths λ1-λ3, respectively. For example, the wavelength λ1 ranges from 900 nm to 950 nm, the wavelength λ2 ranges from 1040 nm to 1065 nm, and the wavelength λ3 ranges from 1300 nm to 1350 nm.

As shown in FIG. 1, in the first embodiment, the second reflector 116 is disposed on the light-emitting surface of the solid laser medium layer 131 through the top reflective layer 133 of the third reflector 128. In contrast, in the sixth embodiment, the second reflector 116 is directly disposed on the light-emitting surface of the solid laser medium layer 131, and the top reflective layer 133 of the third reflector 128 is disposed on the second reflector 116.

Each surface-emitting laser device 115 of the sixth embodiment has a similar structure to the surface-emitting laser device 115 of the first embodiment. The p-type electrode 118 is electrically separated between the surface-emitting laser devices 115. The laser apparatus 105 further includes a light emission controller (not shown) for controlling light emission timing of each surface-emitting laser device 115. Thus, each surface-emitting laser device 115 can be individually controlled by the light emission controller.

The bottom and top reflective layers 132, 133 of the third reflector 128 are configured to provide three different structures, respectively, corresponding to the regions 1-3. The excitation light emitted from the surface-emitting laser devices 115 resonate at the wavelengths λ1-λ3 in the respective structures. For example, the difference in structure results from a difference in at least one of the material (i.e., refractive index), the thickness, the number of pairs of layers (i.e., period) of the bottom and top reflective layers 132, 133.

Like the first embodiment, each of the bottom and top reflective layers 132, 133 is formed with multiple pairs of Al₂O₃/TiO₂ layers. As shown in FIG. 11, each of the bottom and top reflective layers 132, 133 are formed from a first layer 135, a second layer 136, and a third layer 137. The optical thickness of each layer (i.e., each of the Al₂O₃ layer and the TiO₂ layer) of the first layer 135 is set to a quarter of the wavelength λ1 so that the first layer 135 can highly reflect light with the wavelength λ1. Likewise, the optical thickness of each layer (i.e., each of the Al₂O₃ layer and the TiO₂ layer) of the second layer 136 is set to a quarter of the wavelength λ2 so that the second layer 136 can highly reflect light with the wavelength λ2. Likewise, the optical thickness of each layer (i.e., each of the Al₂O₃ layer and the TiO₂ layer) of the third layer 137 is set to a quarter of the wavelength λ3 so that the third layer 137 can highly reflect light with the wavelength λ3.

The layers 135-137 of the top reflective layer 133 are stacked in a first order on the light-emitting surface of the solid laser medium layer 131. The layers 135-137 are stacked in a second order on the light receiving surface of the solid laser medium layer 131. The first order is the reverse of the second order.

Unnecessary layers of the bottom and top reflective layers 132, 133 are removed by etching and photolithograph processes, so that the first, second, and third layers 135-137 become the outermost layer in the bottom and top reflective layers 132, 133 at the regions 1-3, respectively. Specifically, as shown in FIG. 11, at the region 1, the second and third layers 136, 137 on the light-emitting surface of the solid layer medium layer 131 are removed. At the region 2, the third layer 137 on the light-emitting surface of the solid layer medium layer 131 and the first layer 135 on the light receiving surface of the solid layer medium layer 131 are removed. At the region 3, the first and second layers 135, 136 on the light receiving surface of the solid layer medium layer 131 are removed.

A reflectivity of the first layer 135 with respect to the wavelength λ1 is set greater in the bottom reflective layer 132 than in the top reflective layer 133. Thus, at the region 1, the light with the wavelength λ1 resonates between the first layers 135 of the bottom and top reflective layers 132, 133 and is emitted through the top reflective layer 133. Likewise, a reflectivity of the second layer 136 with respect to the wavelength λ2 is set greater in the bottom reflective layer 132 than in the top reflective layer 133. Thus, at the region 2, the light with the wavelength λ2 resonates between the second layers 136 of the bottom and top reflective layers 132, 133 and is emitted through the top reflective layer 133. Likewise, a reflectivity of the third layer 137 with respect to the wavelength λ3 is set greater in the bottom reflective layer 132 than in the top reflective layer 133. Thus, at the region 3, the light with the wavelength λ3 resonates between the third layers 137 of the bottom and top reflective layers 132, 133 and is emitted through the top reflective layer 133.

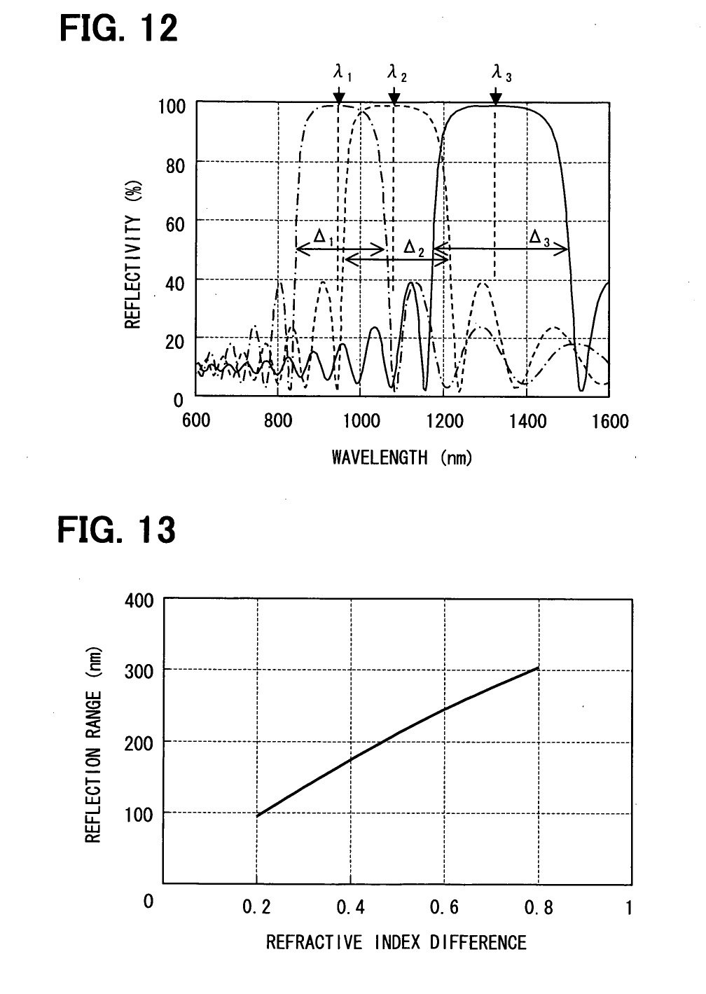

In FIG. 12, Δ1-Δ3 represent high reflection ranges of the layers 135-137 with the center of peak wavelengths λ1-λ3, respectively. For example, light with a wavelength in a high reflection range is reflected with a reflectivity of more than 50%. As can been seen from FIG. 12, the high reflection ranges Δ1-Δ3 are set not to include adjacent peak wavelengths λ1-λ3. Specifically, the high reflection range Δ1 of the layer 135 corresponding to the peak wavelength λ1 does not include the adjacent peak wavelength λ2. The high reflection range Δ2 of the layer 136 corresponding to the peak wavelength λ2 does not include the adjacent peak wavelengths λ1, λ3. The high reflection range Δ3 of the layer 137 corresponding to the peak wavelength λ3 does not include the adjacent peak wavelengths λ2. In such an approach, the light with the wavelengths λ1-λ3 can be selectively resonated only at the respective regions 1-3.

When the following inequalities are satisfied, the high reflection ranges Δ1, Δ2 of the layers 135, 136 can be set not to include the adjacent peak wavelengths λ1-λ3.

|λ1-λ2|>Δ1/2 (3)

|λ1-λ2|>Δ2/2 (4)

When the following inequalities are satisfied, the high reflection ranges Δ2, Δ3 of the layers 136, 137 can be set not to include the adjacent peak wavelengths λ1-λ3.

|λ2-λ3|>Δ2/2 (5)

|λ2-λ3|>Δ3/2 (6)

As shown in FIG. 13, the high reflection ranges Δ1-Δ3 can be adjusted by adjusting differences in refractive indexes between the layers 135-137. For example, when the wavelengths λ1, λ2 are 946 nm, 1064 nm, respectively, each of the high reflection ranges Δ1, Δ2 can be less than 236 nm by setting a difference in refractive indexes between the layers 135, 136 below 0.57.

As described above, according to the laser apparatus 105 of the sixth embodiment, the bottom and top reflective layers 132, 133 of the third reflector 128 are configured to provide three different structures serving as resonators, respectively, corresponding to the regions 1-3. In such an approach, the laser apparatus 105 can output multiple laser light with different wavelengths λ1-λ3 at a time by receiving excitation light with a single wavelength λ0 from the excitation light generator 110.

The resonators are provided on a same plane so that the laser apparatus 105 can be reduced in size. Further, since the surface-emitting laser devices 115 are arranged on the semiconductor substrate 11 in a two-dimensional array, the laser apparatus 105 can be reduced in size.

The surface-emitting laser devices 115 are electrically separated from each other to be individually controlled. Therefore, brightness and colure of the laser light outputted from the laser apparatus 105 can be adjusted by individually controlling the surface-emitting laser devices 115.

In the sixth embodiment, the bottom and top reflective layers 132, 133 of the third reflector 128 are formed by stacking the layers 135-137 over the entire regions 1-3 and then removing unnecessary layers by using etching and photolithograph processes. Alternatively, the bottom and top reflective layers 132, 133 of the third reflector 128 can be formed by stacking the layers 135-137 only on the respective regions 1-3. In such an approach, each of the bottom and top reflective layers 132, 133 is reduced in thickness so that the laser apparatus 105 can be reduced in size.

In the sixth embodiment, the wavelength converter 130 is divided into three regions. Alternatively, the wavelength converter 130 can be divided into two regions or four or more regions.

### Seventh Embodiment

A laser apparatus 106 according to a seventh embodiment of the present invention is described below with reference to FIG. 14. Like the six embodiment, the laser apparatus 101 of the second embodiment is modified as the laser apparatus 106 to output multiple laser light with different wavelengths at a time. Further, as described in the second embodiment, the laser apparatus 106 can have improved heat dissipation efficiency.

### Eighth Embodiment

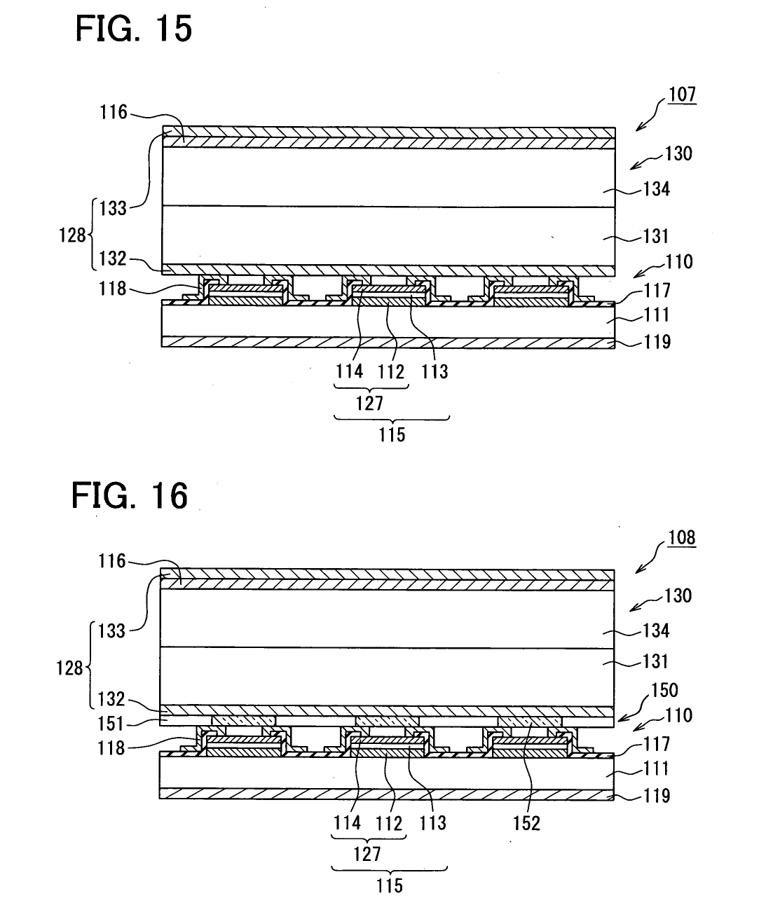

A laser apparatus 107 according to an eighth embodiment of the present invention is described below with reference to FIG. 15. Like the six embodiment, the laser apparatus 102 of the third embodiment is modified as the laser apparatus 107 to output multiple laser light with different wavelengths at a time. For example, when the wavelength conversion element 134 is the nonlinear crystal to generate the second harmonic of the light from the solid laser medium layer 131, the laser apparatus 107 can output multiple light with wavelengths of between 450 nm and 475 nm, between 520 nm and 533 nm, and between 650 nm and 675 nm. Therefore, the laser apparatus 107 can output red, green, and blue light at a time. The eighth embodiment can be combined together with the seventh embodiment.

### Ninth Embodiment

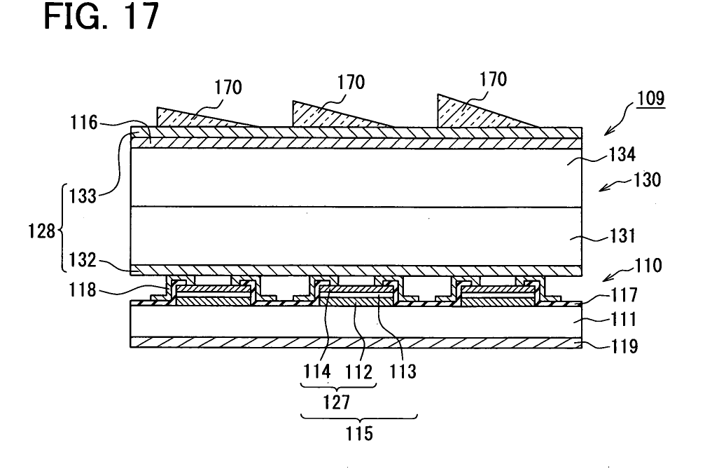

A laser apparatus 108 according to a ninth embodiment of the present invention is described below with reference to FIG. 16. Like the six embodiment, the laser apparatus 103 of the fourth embodiment is modified as the laser apparatus 108 to output multiple laser light with different wavelengths at a time. Further, as described in the fourth embodiment, the laser apparatus 108 can achieve high power laser output. The ninth embodiment can be combined together with the sixth embodiment or seventh embodiment.

### Tenth Embodiment

A laser apparatus 109 according to a tenth embodiment of the present invention is described below with reference to FIG. 17. Like the six embodiment, the laser apparatus 104 of the fifth embodiment is modified as the laser apparatus 109 to output multiple laser light with different wavelengths at a time. Further, as described in the fifth embodiment, the laser apparatus 109 can control the direction of the laser light. The tenth embodiment can be combined together with the sixth embodiment, the seventh embodiment, or the ninth embodiment. Further, the tenth embodiment can be combined together with both the seventh embodiment and the ninth embodiment.

(Modifications)

The embodiment described above may be modified in various ways. For example, although the laser apparatus includes a plurality of surface-emitting laser devices 115 arranged on a single semiconductor substrate 111 in a two-dimensional array, the wavelength converter 130 is not divided into a plurality of regions. In such an approach, the solid laser medium layer 131 of the wavelength converter 130 can be excited by high power excitation light produced by many surface-emitting laser devices 115. Thus, the laser apparatus can achieve high power laser output. Further, since the surface-emitting laser devices 115 are arranged in a two-dimensional array, the laser apparatus can be reduced in size.

Such changes and modifications are to be understood as being within the scope of the present invention as defined by the appended claims.

What is claimed is:

1. A laser apparatus comprising:
an excitation light generator for emitting excitation light, the excitation light generator including at least one surface-emitting laser device that is formed on a semiconductor substrate and includes a first reflector having top and bottom reflectors and a semiconductor active layer disposed between the top and bottom reflectors, the excitation light being emitted through the top reflector of the surface-emitting laser device; and
a wavelength converter including a solid laser medium layer that receives the excitation light and emits laser light by converting a wavelength of the excitation light,
wherein the excitation light generator further includes a second reflector configured to highly reflect the excitation light,
wherein the solid laser medium layer is disposed between the surface-emitting laser device and the second reflector,
wherein a first reflectivity of the top reflector of the first reflector is greater than a second reflectivity of the bottom reflector of the first reflector,
wherein the first and second reflectivities satisfy the following inequality,
$$FWHM > \frac{λ 0 ( 1 - R 1 \cdot R 2 )}{2 {π ( R 1 \cdot R 2 )}^{0.25}}$$
wherein R1, R2 represent the first and second reflectivities, respectively,
wherein λ0 represents the wavelength of the excitation light, and
wherein FWHM represents a full width at half maximum of an absorption spectrum of the solid laser medium layer at the wavelength of the excitation light.

2. The laser apparatus according to claim 1,
wherein the top reflector of the first reflector is formed from a plurality of first type layers stacked together,
wherein the bottom reflector of the first reflector is formed from a plurality of second type layers stacked together,
wherein the first and second type layers are identical in composition,
wherein the first reflectivity of the top reflector depends on the number of the first type layers, and
wherein the second reflectivity of the bottom reflector depends on the number of the second type layers.

3. The laser apparatus according to claim 2,
wherein each of the first and second type layers is a Al_{z1}Ga_{1-z1}As/Al_{z2}Ga_{1-z2}As layer, where 0≦z1<z2≦1.

4. The laser apparatus according to claim 3,
wherein each of the first and second type layers is a Al_{z1}Ga_{1-z1}As/AlAs layer, where 0<z1<1.

5. The laser apparatus according to claim 1,
wherein the bottom reflector, the active layer, and the top reflector are stacked in this order from a side of the semiconductor substrate.

6. The laser apparatus according to claim 1,
wherein the top reflector, the active layer, and the bottom reflector are stacked in this order from a side of the semiconductor substrate, and
wherein the semiconductor substrate has an opening for allowing the excitation light emitted through the top reflector to reach the solid laser medium layer without being obstructed by the semiconductor substrate.

7. The laser apparatus according to claim 1,
wherein the wavelength converter further includes a wavelength conversion element that is disposed on a light-emitting surface of the solid laser medium layer to receive the laser light from the solid laser medium layer, and
wherein the wavelength conversion element converts a wavelength of the laser light.

8. The laser apparatus according to claim 7,
wherein the wavelength conversion element is formed from a nonlinear crystal to generate the second harmonic of the laser light.

9. The laser apparatus according to claim 7,
wherein the wavelength conversion element is integrally formed with the solid laser medium layer.

10. The laser apparatus according to claim 1, further comprising:
a microlens configured to collimate or gather light,
wherein the microlens is disposed on a light-emitting surface of the wavelength converter or disposed between a light-emitting surface of the excitation light generator and a light receiving surface of the wavelength converter.

11. The laser apparatus according to claim 1, further comprising:
an optical element disposed on a light-emitting surface of the wavelength converter and configured to control a direction of the laser light emitted from the wavelength converter.

12. The laser apparatus according to claim 1,
wherein the active layer includes a Alₓ₁In_{y1}Ga_{1-x1-y1}As quantum well layer.

13. The laser apparatus according to claim 1,
wherein the active layer includes a Inₓ₂Ga₁₋ₓ₂As_{y2}P_{1-y2} quantum well layer.

14. The laser apparatus according to claim 1,
wherein the wavelength converter further includes a third reflector configured to highly reflect the laser light, and
wherein the third reflector includes a top reflector disposed on a light-emitting surface side of the solid laser medium layer and a bottom reflector disposed on a light receiving surface side of the solid laser medium layer.

15. The laser apparatus according to claim 14,
wherein the third reflector is integrally stacked on the solid laser medium layer,
wherein the second reflector is integrally stacked on the light-emitting surface side of the solid laser medium layer through the top reflector of the third reflector, and
wherein the excitation light generator and the wavelength converter are integrally formed together.

16. The laser apparatus according to claim 1,
wherein the excitation light generator includes a plurality of surface-emitting laser devices that are arranged on the semiconductor substrate in a two-dimensional array.

17. The laser apparatus according to claim 14,
wherein the excitation light generator includes a plurality of surface-emitting laser devices that are arranged on the semiconductor substrate in a two-dimensional array,
wherein the wavelength converter is divided into a plurality of regions, and
wherein each region of the wavelength converter is provided with a corresponding one of the plurality of surface-emitting laser devices and has a different structure to emit laser light with a corresponding different wavelength.

18. The laser apparatus according to claim 17,
wherein the difference in structure of each region of the wavelength converter results from a structure of the third reflector.

19. The laser apparatus according to claim 18,
wherein the top reflector of the third reflector includes a plurality of reflection layers stacked together in a first order from the light-emitting surface side of the solid laser medium layer,
wherein the bottom reflector of the third reflector includes a plurality of reflection layers stacked together in a second order from the light receiving surface side of the solid laser medium layer,
wherein the first order is the reverse of the second order, and
wherein each of the plurality of reflection layers is configured to highly reflect the laser light with the corresponding different wavelength and disposed on the outermost layer of the plurality of reflection layers at the corresponding region of the wavelength converter.

20. The laser apparatus according to claim 19,
wherein each of the plurality of reflection layers includes first and second layers having different refractive indexes and alternately stacked together, and
wherein an optical thickness of each of the first and second layers is approximately equal to a quarter of the corresponding different wavelength.

21. The laser apparatus according to claim 19,
wherein a first one of the plurality of reflection layers has a first high reflection range with a center of a first one of the corresponding different wavelengths,
wherein a second one of the plurality of reflection layers has a second high reflection range with a center of a second one of the corresponding different wavelengths
wherein the first one of the corresponding different wavelengths is adjacent to the second one of the corresponding different wavelengths,
wherein the first and second high reflection ranges satisfy the following two inequalities,

|λ1-λ2|>Δ1/2

|λ1-λ2|>Δ2/2
wherein λ1 represents the first one of the corresponding different wavelengths,
wherein λ2 represents the second one of the corresponding different wavelengths,
wherein Δ1 represents the first high reflection range, and
wherein Δ2 represents the second high reflection range.

22. The laser apparatus according to claim 18,
wherein the solid laser medium layer includes a neodymium doped crystal.

23. The laser apparatus according to claim 16,
wherein each surface-emitting laser device is individually controlled.
